(19) United States
(12) Patent Application Publication
(10) Pub. No.: US 2025/0253126 A1
(43) Pub. Date: Aug. 7, 2025

(54) CHARGED PARTICLE BEAM WRITING APPARATUS, SHOT DATA CORRECTION METHOD AND CHARGED PARTICLE BEAM WRITING METHOD

(71) Applicant: NuFlare Technology, Inc., Yokohama-shi (JP)

(72) Inventor: Jumpei YASUDA, Kamakura-shi (JP)

(73) Assignee: NuFlare Technology, Inc., Yokohama-shi (JP)

(21) Appl. No.: 19/027,707

(22) Filed: Jan. 17, 2025

(30) Foreign Application Priority Data
Feb. 1, 2024 (JP) 2024-014307

(51) Int. Cl. H01J 37/304; H01J 37/20; H01J 37/317; H01L 21/263; H01L 21/66

(52) U.S. Cl. CPC H01J 37/304; H01J 37/20; H01J 37/3174; H01L 21/263; H01L 22/20; H01J 2237/202; H01J 2237/30455

(57) ABSTRACT

In one embodiment, a charged particle beam writing apparatus includes an emitter emitting a charged particle beam, a movable stage on which a substrate as a writing target is placed, a shot data corrector correcting shot data generated from writing data using a previously determined relationship between a speed of the stage and a positional deviation amount caused by change in the speed of the stage, and a writer irradiating the substrate with the charged particle beam using the corrected shot data, and writing a pattern sequentially on each of a plurality of stripe regions obtained by dividing a writing region of the substrate with a predetermined width.

### CROSS REFERENCE TO RELATED APPLICATION

This application is based upon and claims benefit of priority from the Japanese Patent Application No. 2024-14307, filed on Feb. 1, 2024, the entire contents of which are incorporated herein by reference.

### FIELD

The present invention relates to a charged particle beam writing apparatus, a shot data correction method and a charged particle beam writing method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

Electron beam writing apparatuses write a pattern to a substrate on a moving stage while measuring the stage position. Vibration control by a vibration isolation table has been performed in the past because the vibration occurred due to the stage movement deteriorates the writing accuracy; however, due to restrictions on mechanical vibration characteristics, control vibration may not be performed effectively. For example, in an elongated structure such as a column, when vibration in a mode that causes the structure to bend is excited, the vibration is hardly detected in a vibration isolation table.

Japanese Unexamined Patent Application Publication No. 9-246134 states that a sensor is mounted on a column, a sensor signal is analyzed, a beam deviation amount is calculated and corrected. However, the effect of noise in the sensor is always on, and the beam deviation amount cannot be corrected sufficiently. In addition, a system to process a sensor signal and a noise needs to be installed according to the types and number of sensors, which causes a problem of increased cost.

### BRIEF DESCRIPTION OF THE DRAWINGS

FIG. 1 is a schematic view of an electron beam writing apparatus according to an embodiment of the present invention.

FIG. 2 is a view for explaining an example of a writing operation.

FIG. 3A is a graph showing an example of change in the stage speed, and FIG. 3B is a graph showing an example of change in beam irradiation position deviation amount.

FIG. 4 is a flowchart for explaining a writing method for evaluation pattern.

FIG. 5 is a flowchart for explaining a writing method for reference pattern.

FIG. 6 is a flowchart for explaining an electron beam writing method according to the embodiment.

### DETAILED DESCRIPTION

In one embodiment, a charged particle beam writing apparatus includes an emitter emitting a charged particle beam, a movable stage on which a substrate as a writing target is placed, a shot data corrector correcting shot data generated from writing data using a previously determined relationship between a speed of the stage and a positional deviation amount caused by change in the speed of the stage, and a writer irradiating the substrate with the charged particle beam using the corrected shot data, and writing a pattern sequentially on each of a plurality of stripe regions obtained by dividing a writing region of the substrate with a predetermined width.

Hereinafter, an embodiment of the present invention will be described based on the drawings. In the present embodiment, a configuration using an electron beam as an example of a charged particle beam will be described. The charged particle beam is not limited to an electron beam, and may be a beam using another charged particle, such as an ion beam.

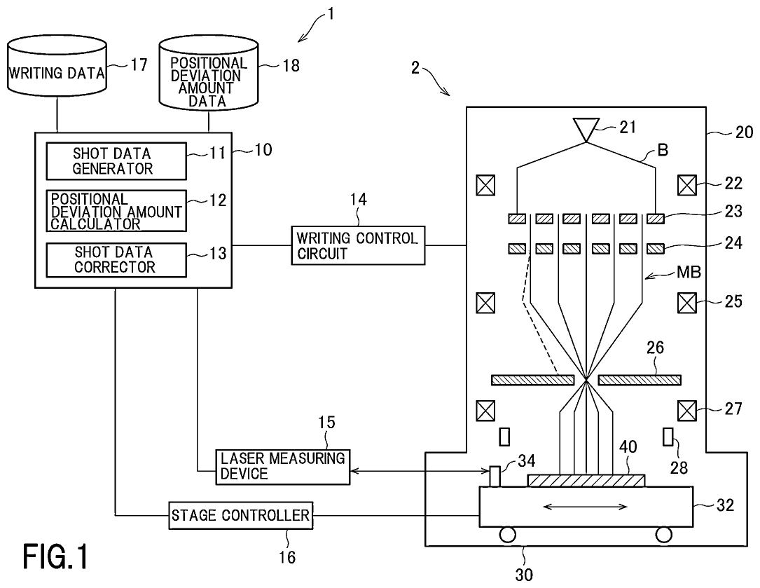

FIG. 1 is a schematic view of a writing apparatus according to the present embodiment. The writing apparatus includes a controller 1 and a writer 2. The writing apparatus is an example of a multi-charged particle beam writing apparatus. The writer 2 includes an electron optical column 20 and a writing chamber 30. In the electron optical column 20, an electron source 21, an illumination lens 22, a shaping aperture array substrate 23, a blanking aperture array substrate 24, a reduction lens 25, a limiting aperture member 26, an objective lens 27, and a deflector 28 are disposed. Both the reduction lens 25 and the objective lens 27 are comprised of an electromagnetic lens, and a reduction optical system is formed by the reduction lens 25 and the objective lens 27.

In the writing chamber 30, an XY stage 32 is disposed. A substrate 40 as a writing target is placed on the XY stage 32. The substrate 40 is an exposure mask when a semiconductor device is fabricated, a semiconductor substrate (silicon wafer) on which a semiconductor device is fabricated, or a mask blank coated with resist, to which nothing has been written.

On the XY stage 32, a mirror 34 is disposed to perform position measurement using a laser.

The controller 1 includes storages 17 and 18 such as magnetic disk drives, a control computer 10, a writing control circuit 14, a laser measuring device 15, and a stage controller 16.

The control computer 10 includes a shot data generator 11, a positional deviation amount calculator 12, and a shot data corrector 13. The shot data generator 11, the positional deviation amount calculator 12, and the shot data corrector 13 may be implemented by software such as a program which causes a computer to execute a process. Alternatively, those components may be implemented by hardware such as an electric device or an electronic device. Alternatively, those components may be implemented by a combination of software and hardware. Alternatively, those components may be implemented by a combination of firmware and hardware.

The laser measuring device 15 irradiates the mirror 34 with a laser, receives a reflected light to measure the position of the XY stage 32, and outputs the stage position to the control computer 10.

The stage controller 16 outputs a stage control signal to control the speed and the acceleration of the XY stage 32.

The writing control circuit 14 controls and drives each device in the writer 2.

In FIG. 1, the components necessary for explaining the embodiment are illustrated. Other components which are normally necessary for the writing apparatus may be included.

In the shaping aperture array substrate 23 installed in the electron optical column 20, openings in m rows and n columns (m, n≥2) are formed in a matrix form with a predetermined arrangement pitch. The openings are formed in rectangular or circular shapes all having the same dimensions.

An electron beam B emitted from the electron source 21 illuminates the entire shaping aperture array substrate 23 substantially perpendicularly via the illumination lens 22. The electron beam B passes through the plurality of openings of the shaping aperture array substrate 23, thereby forming a multi-beam MB including individual beams in m rows and n columns.

Passage holes corresponding to the arrangement positions of the plurality of openings of the shaping aperture array substrate 23 are formed in the blanking aperture array substrate 24. A set of two electrodes (blanker, blanking deflector) as a pair is disposed in each passage hole. An amplifier to apply a voltage is disposed at one of the two electrodes for each beam, and the other electrode is grounded. The individual beams passing through passage holes are each independently deflected by the voltage applied to the two electrodes as a pair. Each beam is blanking-controlled by deflection of the individual beam.

The multi-beam MB which has passed through the blanking aperture array substrate 24 is reduced by the reduction lens 25, and travels to the central opening formed in the limiting aperture member 26. An individual beam deflected by a blanker of the blanking aperture array substrate 24 is deviated from the central opening of the limiting aperture member 26, and is blocked by the limiting aperture member 26. In contrast, an individual beam not deflected by a blanker passes through the central opening of the limiting aperture member 26.

In this manner, the limiting aperture member 26 blocks each beam deflected by a blanker to achieve a beam OFF state. The beam for one shot is formed by the beam which has passed through the limiting aperture member 26 since beam-ON until beam-OFF is achieved.

The multi-beam MB which has passed through the limiting aperture member 26 is focused by the objective lens 27 to form a pattern image with a desired reduction factor, and is collectively deflected by the deflector 28 to be radiated to the substrate 40. For example, when the XY stage 32 is continuously moved, the irradiation position of the beam is controlled by the deflector 28 so that the irradiation position follows the movement of the XY stage 32.

The multi-beam MB is ideally arranged with a pitch which is the product of the arrangement pitch of the plurality of openings of the shaping aperture array substrate 23 and the above-mentioned desired reduction factor. The writing apparatus performs a writing operation by a raster scan method in which a shot beam is sequentially radiated continuously, and when a desired pattern is written, necessary beams are controlled at beam ON according to the pattern by the blanking control.

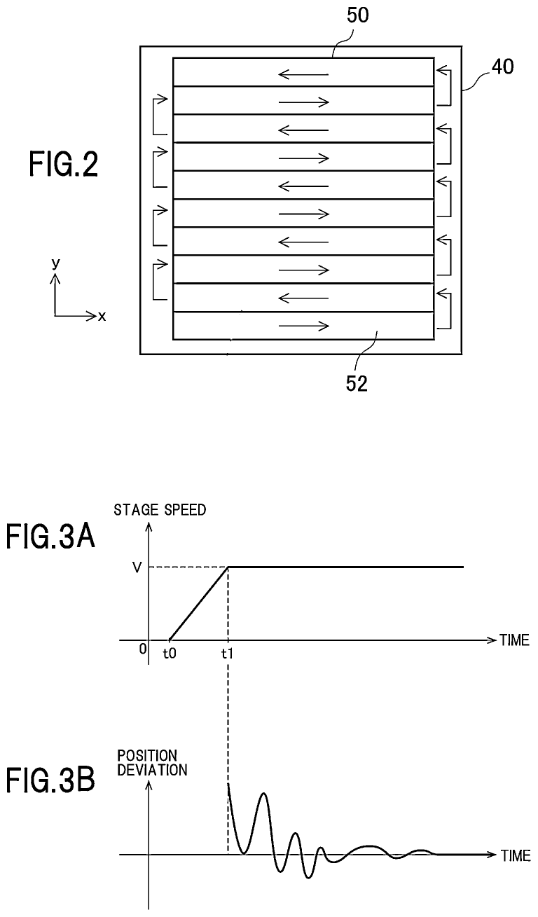

As illustrated in FIG. 2, a writing region 50 of the substrate 40 is virtually divided into e.g., a plurality of stripe regions 52 in a rectangular shape with a predetermined width in y direction. Each stripe region 52 is a writing unit region. For example, the XY stage 32 is moved, and adjustment is made so that an irradiation region which can be irradiated with single irradiation of the multi-beam MB is located at the left end of the first stripe region 52, and writing is started. The writing can proceed relatively in x direction (FWD writing) by moving the XY stage 32 in −x direction.

After writing on the first stripe region 52 is finished, the stage position is moved in −y direction, and adjustment is made so that the irradiation region is located at the right end of the second stripe region 52, and writing is started. The writing proceeds in −x direction (BWD writing), for example, by moving the XY stage 32 in x direction.

The writing time can be reduced by performing writing while alternately changing the direction, for example, performing writing in x direction on the third stripe region 52, and performing writing in −x direction on the fourth stripe region 52. However, writing is not necessarily performed while alternately changing the direction, and when writing is performed on stripe regions 52, writing may proceed in the same direction.

The writing apparatus accelerates the XY stage 32, and upon reaching a predetermined speed, keeps the stage speed to be constant, and starts pattern writing. For example, as illustrated in FIG. 3A, the writing apparatus starts acceleration of the XY stage 32 at time t0, and upon reaching a predetermined speed V at time t1, writes a pattern on the stripe region 52 while maintaining the stage speed at constant.

It is known that in the writing apparatus, the mechanical vibration generated by the movement of the XY stage 32 deteriorates the writing accuracy, and as a result of intensive study to solve this problem, the inventor has obtained knowledge that as illustrated in FIG. 3B, the deviation in the beam irradiation position immediately after the start of writing of the stripe region 52 (at the head portion of the stripe region 52) is large, then the positional deviation gradually decreases. The inventor has found that the above-mentioned problem can be solved by measuring in advance the positional deviation amount of the beam irradiation position, occurred due to the stage movement, for example, the positional deviation amount caused by mechanical vibration, and correcting the beam irradiation position at the time of pattern writing based on the positional deviation amount measured in advance.

The positional deviation amount of the beam irradiation position, occurred due to the stage movement can be determined by writing an evaluation pattern and a reference pattern, and calculating the difference between the writing position of the evaluation pattern and the writing position of the reference pattern.

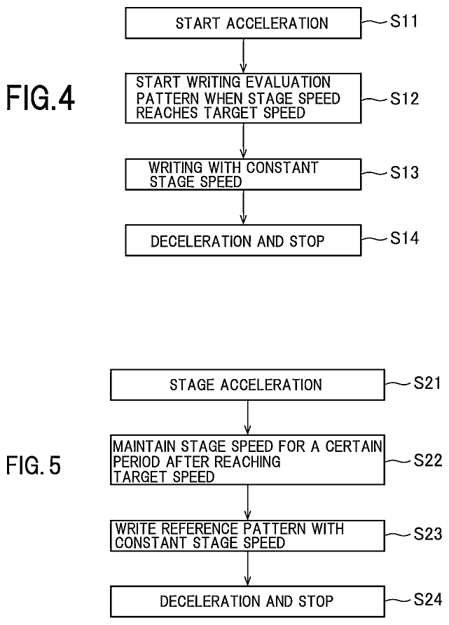

FIG. 4 is a flowchart for explaining a writing method for evaluation pattern. Acceleration of the XY stage 32 is started (step S11), when the stage speed reaches a target speed, the acceleration is stopped, the stage speed is kept constant, and an evaluation pattern is written to a substrate for evaluation, which is coated with a resist (step S12, S13). The shape of the evaluation pattern is not limited to a specific one, and may be a line and space pattern, or a dot pattern. After the evaluation pattern is written, the XY stage 32 is decelerated, and stopped (step S14).

FIG. 5 is a flowchart for explaining a writing method for reference pattern. Acceleration of the XY stage 32 is started (step S21), and when the stage speed reaches a target speed, the stage speed is maintained for a certain period of time (step S22). After lapse of a certain period of time, a reference pattern is written to the substrate for evaluation while maintaining the stage speed (step S23). The shape of the reference pattern is the same as that of the evaluation pattern. After the reference pattern is written, the XY stage 32 is decelerated, and stopped (step S24).

It is preferable that the reference pattern be written in the vicinity of the evaluation pattern. Thus, as compared to when the evaluation pattern is written, when the reference pattern is written, for the substrate for evaluation, acceleration of the XY stage 32 is started from a position away from a multi-beam irradiation possible region, and when a certain period of time elapses since the stage speed reached a target speed, the substrate for evaluation is irradiated with the multi-beam.

The evaluation pattern is started to be written when the stage speed reaches a target speed, thus includes the positional deviation amount of the beam irradiation position caused by the mechanical vibration occurred due to the stage movement. In contrast, the reference pattern is written after lapse of a certain period of time since the stage speed reached a target speed, thus includes an extremely small positional deviation amount of the beam irradiation position caused by the mechanical vibration occurred due to the stage movement.

After the evaluation pattern and the reference pattern are written, a process such as development is performed, and the position of a resist pattern formed (evaluation pattern and reference pattern) is measured using a position measuring instrument. The positional error components due to a factor other than the vibration are removed by subtracting the difference between the writing position of the reference pattern and the design position from the difference between the writing position of the evaluation pattern and the design position, thereby positional deviation amount data of the irradiation position of each beam caused by vibration can be obtained. The positional deviation amount data is map data that defines the positional deviation amount in a map format.

The positional deviation amount immediately after the start of writing of the stripe region 52 (at the head portion of the stripe region 52) is large, and gradually decreases (see FIG. 3B). Thus, the positional deviation amount data may be map data with a size of the head portion of the stripe region, for example, about ¼ of the length of the stripe region from the head. The positional deviation amount data may be map data for one stripe region.

The evaluation pattern and the reference pattern are written with a varied target speed, i.e. for a plurality of target speeds, and the positional deviation amount data is obtained. In addition, the positional deviation amount data is obtained in each stage travel direction (FWD writing/BWD writing). The positional deviation amount data is obtained in advance, and stored in a storage 18 (see FIG. 1).

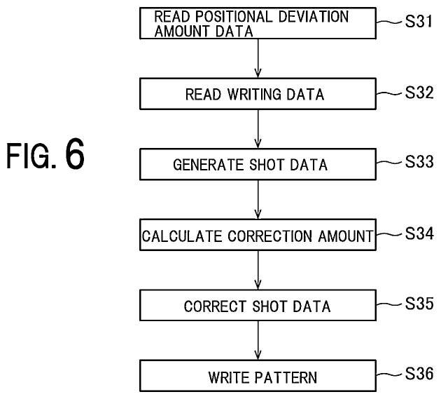

Next, a pattern writing method according to the present embodiment will be described based on the flowchart illustrated in FIG. 6.

The control computer 10 reads the positional deviation amount data from the storage 18 (step S31). Because the stage speed in pattern writing is determined in advance, the control computer 10 reads positional deviation amount data corresponding to the stage speed.

The shot data generator 11 reads writing data from the storage 17 (step S32). For example, the placement coordinates of figure patterns, figure type and figure size are defined in the writing data.

The shot data generator 11 performs multi-stage data conversion on the writing data to generate shot data (step S33). In the shot data, the presence/absence of irradiation and the irradiation amount (irradiation time) to irradiation regions are defined, which are obtained by dividing the writing region 50 of the substrate 40 into, e.g., a plurality of grid-shaped irradiation regions (pixels) with the beam size.

The positional deviation amount calculator 12 refers to the positional deviation amount data read in step S31, and calculates the positional deviation amount of each beam in the stripe region (step S34). The positional deviation amount data referred to is switched depending on the writing proceed direction of the stripe region.

The shot data corrector 13 corrects the shot data so that the beam positional deviation amount calculated in step S34 is corrected (step S35). The positional deviation can be corrected, for example, by assigning a pixel an irradiation amount according to the area ratio for deviation, the pixel being adjacent to the side opposite to the positional deviation direction.

The substrate 40 is irradiated with the multi-beam MB using the corrected shot data to write a pattern (step S36). Using the shot data, the writing control circuit 14 outputs a blanking control signal to a control circuit for individual blanking formed on the blanking aperture array substrate 24, converts the signal to an analog signal in the control circuit, then applies a deflection voltage to electrodes corresponding of a plurality of blankers. Thus, the writing control circuit 14 controls the plurality of blankers using the shot data.

When the stage speed reaches a target speed, the acceleration is stopped, the XY stage 32 is kept constant, and pattern writing is started from the head of the stripe region 52. In the present embodiment, the positional deviation amount of the beam irradiation position caused by the mechanical vibration occurred due to the stage movement is corrected, thus it is possible to effectively reduce the effect of the vibration occurred due to the stage movement on the writing accuracy.

In the above embodiment, the writing apparatus using a multi-beam has been described; however, the present invention is also applicable to a single beam writing apparatus. In the case of single beam, the shot position defined in the shot data is corrected based on the beam positional deviation amount.

In the above embodiment, an example has been described in which the stage speed is kept constant, and a process of writing in the stripe region is performed; however, the stage speed may be changed in the middle of the stripe region. In this case, positional deviation amount data corresponding to the changed stage speed is read from the storage 18, and the shot data after the change of the stage speed is corrected.

When there are many levels of the stage speed, and it is difficult to save the positional deviation amount data for all stage speeds in the storage 18, the positional deviation amount may be saved as a function of time, and may be converted and calculated as a function of position according to the stage speed. For example, the positional deviation amount is decomposed into a plurality of frequency components, and a parameter for each frequency component is maintained as a stage speed dependent parameter.

In the above embodiment, an example has been described in which the positional deviation amount is corrected by correcting the shot position in the shot data; however, the average value of the positional deviation amounts of the beams in the multi-beam may be determined, and the deflection amount of the deflector 28 may be corrected based on the average value.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing apparatus comprising:
an emitter emitting a charged particle beam;
a movable stage on which a substrate as a writing target is placed;
a shot data corrector correcting shot data generated from writing data using a previously determined relationship between a speed of the stage and a positional deviation amount caused by change in the speed of the stage; and
a writer irradiating the substrate with the charged particle beam using the corrected shot data, and writing a pattern sequentially on each of a plurality of stripe regions obtained by dividing a writing region of the substrate with a predetermined width.

2. The apparatus according to claim 1, further comprising
a storage storing a plurality of pieces of positional deviation amount data corresponding to a plurality of stage speeds,
wherein the shot data corrector reads, from the storage, a piece of positional deviation amount data corresponding to a stage speed when the substrate is irradiated with a beam, and corrects the shot data.

3. The apparatus according to claim 1, further comprising
a storage configured to store a function using a variable for a plurality of stage speeds,
wherein the shot data corrector determines a positional deviation amount corresponding to a stage speed when the substrate is irradiated with a beam using the function read from the storage, and corrects the shot data.

4. A shot data correction method for writing a pattern by irradiating a substrate placed on a moving stage with a charged particle beam, the method comprising:
generating the shot data from writing data; and
correcting the shot data corresponding to a beam radiated when change occurs in speed of the stage using a previously determined relationship between a speed of the stage and a positional deviation amount caused by change in the speed of the stage.

5. The method according to claim 4,
wherein the shot data is corrected by use of a plurality of pieces of positional deviation amount data corresponding to a plurality of stage speeds.

6. The method according to claim 4,
wherein the shot data is corrected by use of a function using a variable for a plurality of stage speeds.

7. A charged particle beam writing method by which the substrate placed on the stage which moves in a predetermined direction is irradiated with the charged particle beam, and a pattern is written sequentially using the shot data corrected by the shot data correction method according to claim 4.

8. The method according to claim 7,
wherein the charged particle beam is a multi-beam including a plurality of individual beams.
